(19) United States
(12) Patent Application Publication
(10) Pub. No.: US 2013/0221290 A1
(43) Pub. Date: Aug. 29, 2013

(54) NANOCOMPOSITE THERMOELECTRIC CONVERSION MATERIAL, METHOD OF PRODUCING SAME, AND THERMOELECTRIC CONVERSION ELEMENT

(71) Applicants: Junya Murai, Susono-shi (JP); Takuji Kita, Numazu-shi (JP)

(72) Inventors: Junya Murai, Susono-shi (JP); Takuji Kita, Numazu-shi (JP)

(21) Appl. No.: 13/883,000

(22) PCT Filed: Nov. 7, 2011
(86) PCT No.: PCT/IB11/02618

§ 371 Date: May 2, 2013

(30) Foreign Application Priority Data
Nov. 8, 2010 (JP) 2010-249912

(51) Int. Cl. H01L 35/02

(52) U.S. Cl. CPC H01L 35/02
USPC 252/519.4; 252/500

(57) ABSTRACT

A nanocomposite thermoelectric conversion material is provided in which crystal grains of a thermoelectric material parent phase are stacked in a laminar configuration and are oriented, the width of the crystal grains perpendicular to the direction of this orientation is in a range from at least 5 nm to less than 20 nm, and insulating nanoparticles are present dispersed at the grain boundaries. Also provided is a method of producing a nanocomposite thermoelectric conversion material, by which the crystal grains of a thermoelectric material parent phase are oriented by cooling a material under compression at a cooling rate of at least 1° C./minute to less than 20° C./minute. A thermoelectric conversion element that contains the aforementioned nanocomposite thermoelectric conversion material is also provided.

### CROSS-REFERENCE TO RELATED APPLICATIONS

This application is a national phase application of International Application No. PCT/IB2011/002618, filed Nov. 7, 2011, and claims the priority of Japanese Application No. 2010-249912, filed Nov. 8, 2010, the content of both of which is incorporated herein by reference.

### BACKGROUND OF THE INVENTION

1. Field of the Invention

The invention relates to a nanocomposite thermoelectric conversion material, a method of producing same, and a thermoelectric conversion element that contains same. More particularly, the invention relates to a nanocomposite thermoelectric conversion material that has a large power factor, to a method of producing this nanocomposite thermoelectric conversion material, and to a thermoelectric conversion element that contains this nanocomposite thermoelectric conversion material.

2. Description of Related Art

In order to reduce carbon dioxide emissions in view of the global warming problem, there has been ever increasing interest in technologies that reduce the proportion of energy obtained from fossil fuels. Thermoelectric materials, which can directly convert unused waste thermal energy to electrical energy, are one of these technologies. A thermoelectric material is a material capable of directly converting heat to electrical energy, rendering unnecessary the two-stage process in which, as in a thermal power station, heat is temporarily converted into kinetic energy and this is converted into electrical energy.

The conversion from heat into electrical energy is ordinarily carried out by utilizing a temperature difference between the two ends of a bulk body formed from a thermoelectric material. The phenomenon of voltage generation by this temperature difference is referred to as the Seebeck effect because it was discovered by Seebeck. This property of thermoelectric materials is represented by the figure of merit Z as defined by the following equation.

Z=α²σ/κ(=Pf/κ)

Here, α is the Seebeck coefficient of the thermoelectric material, σ is the electrical conductivity (the reciprocal of the electrical conductivity is called the specific resistance) of the thermoelectric material, and κ is the thermal conductivity of the thermoelectric material. The power factor Pf summarizes the α²σ term. The reciprocal of temperature is the dimension on Z, and ZT, obtained by multiplying the absolute temperature T by the figure of merit Z, is thus a dimensionless value. This ZT is called the dimensionless figure of merit and is used as a parameter that indicates thermoelectric material performance. In order for thermoelectric materials to enter into widespread use, this performance and particularly the performance at low temperatures must undergo additional improvements. As is made clear from the equation provided above, an improvement in thermoelectric material performance requires a lower thermal conductivity κ and a higher power factor, this latter being achieved by a higher Seebeck coefficient α and a higher electrical conductivity σ (smaller specific resistance). However, it is difficult to improve all of these factors at the same time, and there have been numerous attempts at improving one of these thermoelectric material factors with the goal of providing a thermoelectric material also capable of carrying out conversion into electrical energy even at low temperatures.

For example, Japanese Patent Application Publication No. 2004-335796 (JP-A-2004-335796) describes a thermoelectric semiconductor material produced as follows: a plate-shaped thermoelectric semiconductor substance including a starting alloy having a prescribed thermoelectric semiconductor compound composition is stacked and filled in an approximately laminar configuration and is solidified and molded to give a molding, and this molding is subjected to pressing from a uniaxial direction perpendicular or approximately perpendicular to the main stacking direction of the thermoelectric semiconductor substance, in order to carry out plastic deformation such that shear force is applied in a uniaxial direction approximately parallel to the main stacking direction of the thermoelectric semiconductor substance. It is specifically stated that the thermal conductivity can be reduced with a thermoelectric semiconductor material for which the starting molding is made by using the composition of the (Bi—Sb)₂Te₃ system for the stoichiometric composition of the thermoelectric semiconductor compound and adding Te in excess to this stoichiometric composition. However, JP-A-2004-335796 does not describe a nanocomposite thermoelectric conversion material.

According to the related art described above, it is difficult to obtain a large power factor even if the thermal conductivity of the thermoelectric semiconductor material can be reduced and the improvement in the figure of merit is unsatisfactory. In order to achieve additional improvements in the performance of thermoelectric conversion materials, the inventors have filed a patent application (Japanese Patent Application No. 2009-285380) on an invention related to a nanocomposite thermoelectric conversion material in which nanoparticles of a dispersant are dispersed in a thermoelectric material parent phase. This nanocomposite thermoelectric conversion material can provide a significant reduction in the thermal conductivity, but does not change the Seebeck coefficient α, and additional improvements in the figure of merit are thus required.

### SUMMARY OF THE INVENTION

In view of the problem described above, the invention, by improving the Seebeck coefficient α over that of the nonoriented nanocomposite, provides a nanocomposite thermoelectric conversion material that has an increased power factor even at low temperatures. The invention also provides a method of producing this nanocomposite thermoelectric conversion material and a thermoelectric conversion element that contains this nanocomposite thermoelectric conversion material.

In one aspect of the invention, a nanocomposite thermoelectric conversion material is provided in which crystal grains of a thermoelectric material parent phase are stacked in a laminar configuration and are oriented, a width of the crystal grains perpendicular to a direction of this orientation is in a range from at least 5 nm to less than 20 nm, and insulating nanoparticles are present dispersed at the grain boundaries.

In another aspect of the invention, a method of producing a nanocomposite thermoelectric conversion material is provided, this method including subjecting a material that has insulating nanoparticles dispersed in a thermoelectric material parent phase and that is heated to a temperature that is higher than or equal to the softening point of the thermoelectric material, to orientation of the crystal grains of the thermoelectric material parent phase by cooling under compression at a cooling rate of at least 1° C./minute to less than 20° C./minute.

According to another aspect the invention provides the nanocomposite thermoelectric conversion material obtained by the aforementioned method. According to yet another aspect, the invention provides a thermoelectric conversion element that contains the aforementioned nanocomposite thermoelectric conversion material.

In the invention, insulating nanoparticles means finely divided insulating particles having a particle diameter of not more than 100 nm, for example, not more than 50 nm and particularly in the range from 0.1 to 10 nm. The width of the crystal grains perpendicular to the direction of orientation refers in the invention to the width of any randomly selected crystal grain of the thermoelectric material parent phase as determined by the method described in the Examples section below. In addition, the direction of orientation in the invention is the direction parallel to the direction of electron conduction in the nanocomposite thermoelectric conversion material.

A nanocomposite thermoelectric conversion material having an increased power factor can be obtained in accordance with the invention by improving the Seebeck coefficient α, even at low temperatures, over that of the nonoriented nanocomposite thermoelectric conversion material. In addition, the invention makes it possible to easily and conveniently obtain a nanocomposite thermoelectric conversion material having an increased power factor due to an improved Seebeck coefficient α, even at low temperatures, over that of the nonoriented nanocomposite thermoelectric conversion material. The invention can also provide a thermoelectric conversion element that contains a nanocomposite thermoelectric conversion material having an increased power factor due to an improvement in the Seebeck coefficient α, even at low temperatures, over that of the nonoriented nanocomposite thermoelectric conversion material.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1 is an enlarged partial schematic diagram of a nanocomposite thermoelectric conversion material of an embodiment of the invention;

FIG. 2 is an enlarged partial schematic diagram for describing a nanocomposite thermoelectric conversion material of an embodiment of the invention;

FIG. 3 is a schematic diagram of a device that is used to produce a nanocomposite thermoelectric conversion material of an embodiment of the invention;

FIG. 4 is an enlarged schematic diagram of a crystal grain in which insulating nanoparticles are dispersed in a thermoelectric material parent phase, prior to the orientation that is used in an embodiment of the production method of the invention;

FIG. 5 is an enlarged schematic diagram of a crystal grain of a nanocomposite thermoelectric conversion material obtained according to an embodiment of the production method of the invention;

FIG. 6 is a graph that shows a comparison of the Seebeck coefficient of the nanocomposite thermoelectric conversion material obtained in the example with the Seebeck coefficient of the nanocomposite thermoelectric conversion materials obtained in the comparative examples;

FIG. 7 is a graph that shows a comparison of the specific resistance of the nanocomposite thermoelectric conversion material obtained in the example with the specific resistance of the nanocomposite thermoelectric conversion materials obtained in the comparative examples;

FIG. 8 is a graph that shows a comparison of the power factor of the nanocomposite thermoelectric conversion material obtained in the example with the power factor of the nanocomposites obtained in the comparative examples;

FIG. 9 is a graph that shows a comparison of the ZT of the nanocomposite thermoelectric conversion material obtained in the example with the ZT of the nanocomposite thermoelectric conversion materials obtained in the comparative examples;

FIG. 10 is a graph that shows the relationship between the Seebeck coefficient and temperature for a nanocomposite thermoelectric conversion material obtained based on the related art;

FIG. 11 is a graph that shows the relationship between the thermal conductivity and temperature for a nanocomposite thermoelectric conversion material obtained based on the related art;

FIG. 12 is a graph that shows the relationship between ZT and temperature for a nanocomposite thermoelectric conversion material obtained based on the related art;

FIG. 13 is a reproduction of a high-amplification transmission electron microscopy (TEM) image from view A in FIG. 2 of the nanocomposite thermoelectric conversion material obtained in the example;

FIG. 14 is a reproduction of a high-amplification TEM image, at a different amplification and from view A in FIG. 2, of the nanocomposite thermoelectric conversion material obtained in the example;

FIG. 15 is a reproduction of a medium-amplification TEM image from view A in FIG. 2 of the nanocomposite thermoelectric conversion material obtained in the example;

FIG. 16 is a reproduction of an even higher amplification TEM image from view A in FIG. 2 of the nanocomposite thermoelectric conversion material obtained in the example;

FIG. 17 is a reproduction of a high-amplification TEM image from view B in FIG. 2 of the nanocomposite thermoelectric conversion material obtained in the example;

FIG. 18 is a reproduction of a high-amplification TEM image from view A in FIG. 2 of the nanocomposite thermoelectric conversion material obtained in Comparative Example 2;

FIG. 19 is a reproduction of a high-amplification TEM image, at a different amplification and from view A in FIG. 2, of the nanocomposite thermoelectric conversion material obtained in Comparative Example 2; and

FIG. 20 is a schematic diagram of an example of a thermoelectric conversion element of the invention.

### DETAILED DESCRIPTION OF EMBODIMENTS

According to an embodiment of the invention, through a nanocomposite thermoelectric conversion material in which crystal grains of a thermoelectric material parent phase are stacked in a laminar configuration and are oriented, the width of the crystal grains perpendicular to this direction of orientation is in the range from at least 5 nm to less than 20 nm, and insulating nanoparticles are present dispersed at the grain boundaries, a nanocomposite thermoelectric conversion material can be obtained that has an increased power factor due to an improved Seebeck coefficient α in comparison to the nanocomposite thermoelectric conversion material prior to orientation. In addition, by subjecting, according to an embodiment of the invention, a material that has insulating nanoparticles dispersed in a thermoelectric material parent phase and that is heated to a temperature that is greater than or equal to the softening point of the thermoelectric material, to orientation of the crystal grains of the thermoelectric material parent phase by cooling under compression at a cooling rate of at least 1° C./minute to less than 20° C./minute, a nanocomposite thermoelectric conversion material having an increased power factor can be easily and conveniently obtained due to an improved Seebeck coefficient α in comparison to the nanocomposite thermoelectric conversion material prior to orientation. Moreover, the nanocomposite thermoelectric conversion material obtained by this method can provide a nanocomposite thermoelectric conversion material having an increased power factor due to an improved Seebeck coefficient α in comparison to the nanocomposite thermoelectric conversion material prior to orientation. A high-performance element in which the power factor has been increased by improving the Seebeck coefficient α of the nanocomposite thermoelectric conversion material can be obtained according to a further embodiment of the invention by the use of a thermoelectric conversion element that contains the aforementioned nanocomposite thermoelectric conversion material.

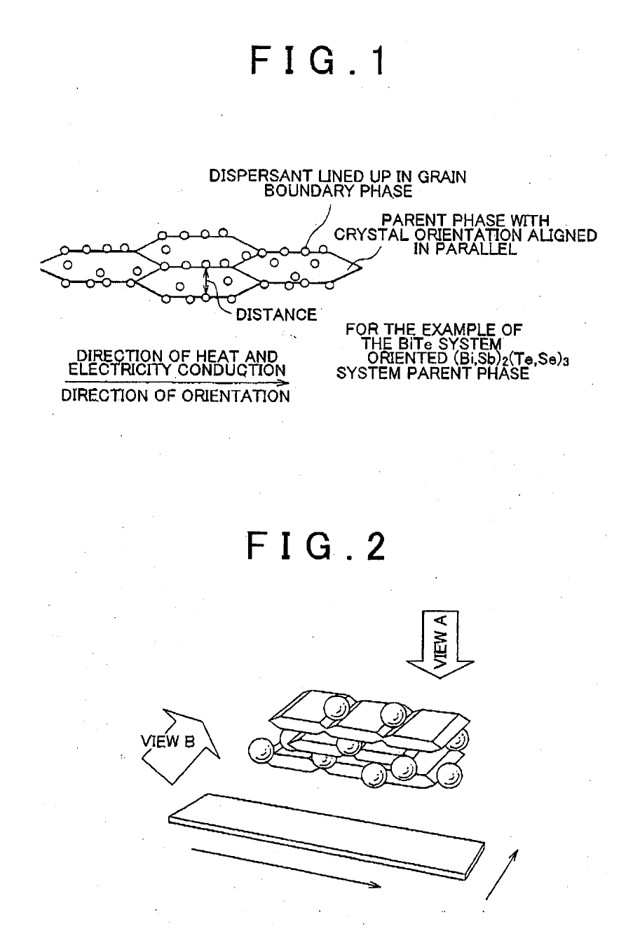

The invention is described below using FIGS. 1 to 20. As shown in FIGS. 1, 2, 5, and 13 to 17, in the nanocomposite thermoelectric conversion material that is an embodiment of the invention, for example, in the case of the (Bi,Sb)₂(Te,Se)₃ crystal grains of the BiTe system, the crystal grains of the parent phase, which has a crystal orientation aligned in parallel, are stacked in a laminar configuration and are aligned and insulating nanoparticles are present dispersed at the grain boundaries. As shown in FIGS. 13 to 16, the width of the crystal grains perpendicular to this direction of orientation is in the range from at least 5 nm to less than 20 nm. As shown in FIG. 2, the direction of conduction for heat and electricity can be in the plane perpendicular to the direction that is compressed. Production is difficult when this post-orientation crystal grain width is smaller than the lower limit indicated above, while no improvement in the Seebeck coefficient α can be expected at greater than or equal to the upper limit indicated above. In contrast to this, as shown in FIGS. 4, 18, and 19, in a nanocomposite thermoelectric conversion material outside the range of the invention, the crystal grains of the parent phase are not oriented and the insulating nanoparticles are present within the crystal grains.

Moreover, as shown in FIGS. 6, 8, 10, and 12, the nanocomposite thermoelectric conversion material according to the embodiment of the invention and having the structure described above has a Seebeck coefficient and a ZT higher than for the conventionally available thermoelectric material described in Journal of Crystal Growth, 277 (2005) 258-263 even in a low temperature range, for example, at temperatures in the range from approximately 30° C. to approximately 50° C. Furthermore, as shown in FIGS. 6 to 9, even in a low temperature range, for example, at temperatures in the range from approximately 30° C. to approximately 50° C., the nanocomposite thermoelectric conversion material according to the embodiment of the invention and having the structure described above, has an increased Seebeck coefficient, a reduced specific resistance, a power factor increased, for example, by about four-fold, and a ZT increased by about four-fold in comparison to the nanocomposite thermoelectric conversion material prior to orientation.

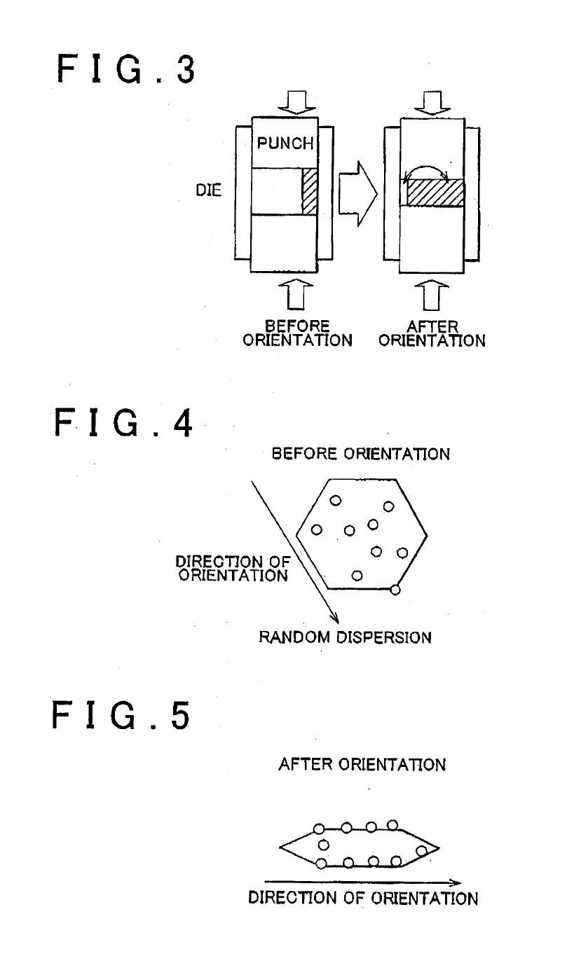

In an embodiment of the invention, the nanocomposite thermoelectric conversion material of the invention can be obtained using, for example, the orientation device shown in FIG. 3, by subjecting a material that has insulating nanoparticles dispersed in a thermoelectric material parent phase and that is heated to a temperature that is greater than or equal to the softening point of the thermoelectric material, to orientation of the crystal grains of the thermoelectric material parent phase by cooling under compression at a cooling rate of at least 1° C./minute to less than 20° C./minute. As shown in FIGS. 6 to 9, the nanocomposite thermoelectric conversion material obtained by the embodiment of the method of the invention has a higher Seebeck coefficient, an equal specific resistance, a higher power factor, and an at least 50% higher ZT in the low temperature range, for example, in the temperature range from approximately 30° C. to approximately 50° C., in comparison to a nanocomposite thermoelectric conversion material obtained using a cooling rate larger than the range described above for the invention, i.e., a quenching method.

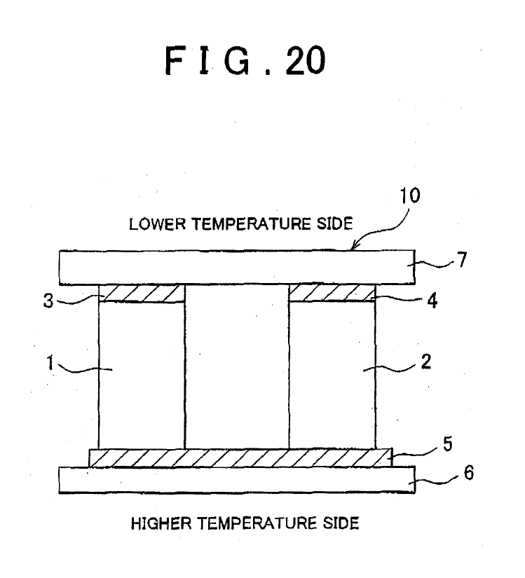

In an embodiment of the invention, a thermoelectric conversion element 10 of the invention has, as shown in FIG. 20, a thermoelectric conversion material 1 (a p-type thermoelectric conversion material main body) formed from a nanocomposite thermoelectric conversion material according to the invention that is a p-type semiconductor, arranged in parallel with a thermoelectric conversion material 2 (an n-type thermoelectric conversion material main body) that is an n-type semiconductor, while a terminal electrode 3, another terminal electrode 4, and a common electrode 5 are connected in series. A lower insulating substrate 6 is connected to the outer side of the common electrode 5. An upper insulating substrate 7 is connected to the outer side of the terminal electrode 3 and the terminal electrode 4. When a temperature difference is applied across the lower and upper insulating substrates 6, 7 using the upper insulating substrate 7 for the lower temperature (L) and the lower insulating substrate 6 for the higher temperature (H), the positively charged holes in the p-type semiconductor thermoelectric conversion material 1 migrate to the lower temperature L side, while in the n-type semiconductor thermoelectric conversion material 2 the negatively charged electrons migrate to the lower temperature side L. A potential difference is produced between the terminal electrode 3 and the terminal electrode 4 as a result. When a temperature difference is applied, the terminal electrode 3 becomes positive and the terminal electrode 4 becomes negative. Higher voltages can be obtained by connecting the p-type thermoelectric conversion material 1 in serial alternation with the n-type thermoelectric conversion material 2.

The dispersant in the invention can be exemplified by inorganic insulating materials, for example, alumina, zirconia, titania, magnesia, silica, composite oxides containing the preceding, silicon carbide, aluminum nitride, and silicon nitride. Among the preceding, silica, zirconia, and titania are advantageous for their low thermal conductivities. A single insulating material may be used as the dispersant or two or more insulating materials may be used in combination as the dispersant.

There are no particular limitations in the invention on the thermoelectric material, and this thermoelectric material can be exemplified by materials that contain at least two or more elements selected from Bi, Sb, Ag, Pb, Ge, Cu, Sn, As, Se, Te, Fe, Mn, Co, and Si, for example, the BiTe system and crystals of a CoSb₃ compound in which Co and Sb are the main components, but which contain an element other than Co and Sb, for example, a transition metal. This transition metal can be exemplified by Cr, Mn, Fe, Ru, Ni, Pt, and Cu. Favorable examples of the thermoelectric material are the (Bi,Sb)₂(Te,Se)₃ system, Bi₂Te₃ system, (Bi,Sb)Te system, Bi(Te,Se) system, CoSb₃ system, PbTe system, and SiGe system. Thermoelectric materials that contain Ni among the aforementioned transition metals, and particularly thermoelectric materials with the chemical composition Co₁₋ₓNiₓSb_{y} (in the formula, 0.03<x<0.09, 2.7<y<3.4), provide n-type thermoelectric materials, while thermoelectric materials that contain Fe, Sn, or Ge in the composition, for example, thermoelectric materials for which the chemical composition is CoSbₚSn_{q} or CoSbₚGe_{q} (in the formula, 2.7<p<3.4, 0<q<0.4, p+q>3), can provide p-type thermoelectric materials.

The material having insulating nanoparticles dispersed in a thermoelectric material parent phase that is used in the method of the invention can be obtained, for example, by carrying out the following sequence: synthesis by the dropwise addition of a solvent solution of a reducing agent into a slurry that contains the salts of precursor substances for the thermoelectric material and nanoparticles of the dispersant; separation and recovery of the solid fraction from the solvent and alloying by a hydrothermal treatment to obtain the thermoelectric material; and drying. The salts of the precursor substances for the thermoelectric material can be exemplified by the salt of at least one or more elements selected from Bi, Sb, Ag, Pb, Ge, Cu, Sn, As, Se, Te, Fe, Mn, Co, and Si, for example, a salt of Bi, Co, Ni, Sn, or Ge, e.g., a halide of these elements such as the chloride, fluoride, or bromide and preferably the chloride, or the sulfate salt, nitrate salt, and so forth of these elements. Examples of other salts of the thermoelectric materials are the salts of elements other than the aforementioned elements, for example, a salt of Sb, e.g., a halide of such elements such as the chloride, fluoride, or bromide and preferably the chloride, or the sulfate salt, nitrate salt, and so forth of such elements.

The solvent used to give the slurry should be capable of uniformly dispersing the aforementioned thermoelectric materials and in particular should be capable of dissolving the aforementioned thermoelectric materials, but is not otherwise particularly limited. This solvent can be exemplified by methanol, ethanol, isopropanol, dimethylacetamide, and N-methylpyrrolidone wherein alcohols such as methanol and ethanol are preferred.

The reducing agent should be capable of reducing the salts of the aforementioned thermoelectric materials, but is not otherwise particularly limited. This reducing agent can be exemplified by tertiary phosphine, secondary phosphine, and primary phosphine, hydrazine, hydroxyphenyl compounds, hydrogen, hydrides, borane, aldehydes, reducing halogen compounds, and multifunctional reductants. More particular examples are at least one alkali borohydride, for example, sodium borohydride, potassium borohydride, and lithium borohydride.

This method provides thermoelectric material/dispersant composite nanoparticles as a slurry in the solvent, for example, ethanol, and the composite nanoparticles are therefore ordinarily filtered and washed using a solvent, for example, ethanol, or a mixed solvent of a large amount of water and a small amount of solvent (for example, water:solvent=100:25 to 75 as the volumetric ratio). Alloying can then be performed by carrying out a hydrothermal treatment in a sealed pressurized vessel, for example, in a sealed autoclave, at a temperature of 200 to 400° C. for at least 10 hours, for example, 10 to 100 hours and particularly about 24 to 100 hours. A powder-form material in which nanoscale composite formation has occurred can then ordinarily be obtained by drying in a nonoxidizing atmosphere, for example, an inert atmosphere.

The method of the invention uses a material in which insulating nanoparticles are dispersed in a thermoelectric material parent phase. This material can be obtained as a bulk body by subjecting the previously described powder-form thermoelectric material starting material to indirect heating (HP) or spark plasma sintering (SPS) at high temperature, for example, 300 to 600° C. This method can provide a bulk material in which nanoparticles of the dispersant are dispersed in a thermoelectric material parent phase, for the production of the nanocomposite thermoelectric conversion material.

This SPS sintering can be performed using an SPS sintering device that is provided with punches (upper, lower), electrodes (upper, lower), dies, and a pressurization apparatus. For the case of HP, current is introduced into a resistance heater that is disposed so as to surround a first die and a second die for the thermoelectric material. The heated resistance heater is employed as a heater to heat the first die and second die and also the thermoelectric material, and as necessary compression is carried out using the dies. In the case of sintering, only the sintering chamber of the sintering device may be isolated from the atmosphere and placed under an inert sintering atmosphere, or the entire system may be enclosed in a housing and placed under an inert atmosphere.

The method of the invention can be carried out by causing orientation of the crystal grains of the thermoelectric material parent phase by heating by SPS sintering or HP and then cooling under compression at a cooling rate of at least 1° C./minute but less than 20° C./minute using a device provided with a compression capability and a cooling capability, for example, as shown in FIG. 3. The bulking that yields the bulk body, and the compression step may be performed using the same device. During strong plastic deformation, slippage is produced at the slip planes of the parent phase and rotation of the material is produced in the compression deformation process. At this point, good rearrangement does not occur when rapid cooling is carried out and the dispersant remains in a random condition; however, it is thought that when gradual cooling conditions are used, arrangement occurs because the sequence from rotation to rearrangement is completed. It is thought that this phenomenon occurs due to gradual cooling from a high temperature greater than or equal to the softening point in a compressed state that brings about strong plastic deformation. The thickness compression rate [(thickness prior to compression of the material−thickness after compression of the material)×100/thickness prior to compression of the material] (%) of the material due to this cooling under compression is suitably in the range from 25 to 90% and particularly 40 to 80%. The pressure during this cooling under compression is suitably in the range from 5 to 500 MPa and particularly is in the range from 50 to 200 MPa. As noted above, an n-type nanocomposite thermoelectric conversion material or a p-type nanocomposite thermoelectric conversion material can be obtained.

Specific descriptions have been provided in this Specification based on combinations of specific thermoelectric materials and dispersants, but the invention is not limited to the thermoelectric material/dispersant combinations with the specific chemical compositions used in the preceding and any combination of thermoelectric material parent phase and dispersant nanoparticles can be used as long as the characteristic features of the invention are satisfied. In addition, a thermoelectric conversion element can be obtained by combining an electrode pair with a nanocomposite thermoelectric conversion material obtained in accordance with the invention.

Examples of the invention are given below. The measurements on the nanocomposite thermoelectric conversion materials obtained in each of the following examples were carried out using the methods given below. The measurement methods given below are provided by way of illustration, and the same measurements can be performed using equivalent measurement methods.

1. High-resolution transmission electron microscope (TEM), observation instrumentation: TECNAI (FEI Company)

2. The high-resolution TEM image is measured, and the determination is made for view B in FIG. 2 for randomly selected crystal grains in the obtained photograph.

3. The thermal diffusivity β of the fabricated nanocomposite thermoelectric conversion material is measured by the flash method, while the specific heat Cp is measured by differential scanning calorimetry (DSC). The density ρ is measured by the Archimedean method. Using the measured thermal diffusivity β, specific heat Cp, and density ρ, the thermal conductivity of the fabricated nanocomposite thermoelectric conversion material is determined from the following formula: thermal conductivity κ=β×Cp×ρ.

4. The measurement is carried out using a ZEM from ULVAC-RIKO, Inc., by the computational method based on the thermoelectromotive force and temperature difference produced by heating one end of the measurement sample and cooling the other end.

5. Measurement is performed by the 4-point probe method using a resistivity meter.

6. This is determined by taking the reciprocal of the specific resistance.

7. The power factor is calculated from the following equation: power factor Pf=α²σ.

8. ZT can be calculated from the following equation.

ZT=α²σT/κ(=PfT/κ)

9. Determination of the softening point: The literature value or the temperature observed in testing in advance (the temperature at which deformation begins when the temperature during the application of pressure is taken) was used.

Liquid-phase synthesis was carried out by the following procedure in Example 1.

### Preparation of the Starting Slurry:

The following starting materials were mixed and slurried in 100 mL ethanol.

| | |
|---|---|
| bismuth chloride (BiCl₃) | 2.0 g |
| antimony chloride (SbCl₃) | 7.34 g |
| tellurium chloride (TeCl₄) | 12.82 g |

Reduction Treatment:

A solution was prepared by dissolving 10 g NaBH₄ as a reducing agent in 1000 mL ethanol, and this solution was added dropwise to the starting slurry.

The ethanol slurry, which contained finely divided alloy particles of Bi, Sb, Te precipitated by the reduction, was filtered and washed with a solution of 500 mL water+300 mL, ethanol and was additionally filtered and washed with 300 mL, ethanol.

Alloying Step:

The recovered powder was alloyed by carrying out a hydrothermal treatment for 48 hours at 240° C. to provide (Bi,Sb)₂Te₃/Sb₂O₃ nanoparticles in which the Sb₂O₃ was dispersed in the Bi, Sb, Te parent phase.

### Drying:

The powder was subsequently recovered by drying in a N₂ gas flow atmosphere. Approximately 2.1 g of an alloy powder was recovered at this point.

### Bulk Body Production:

The recovered powder was subjected to SPS sintering for 15 minutes at 350° C. to fabricate a nanocomposite thermoelectric conversion material bulk body in which 12 volume % Sb₂O₃ having a particle diameter of 10 nm (average) was dispersed as the dispersed phase in a parent material having a softening point of approximately 300° C. and having a (Bi,Sb)₂Te₃ thermoelectric material.

Compression Processing:

Heating and compression were thereafter carried out under the following conditions by SPS; this was followed by cooling.

### Compression Conditions:

| change in the thickness (thickness compression | 50% | |
|---|---|---|
| rate of the material) | | |
| initial pressure (pressure at the start of pressure | 40 | MPa |
| application) | | |
| heating temperature (*) | 350° | C. |
| rate of temperature rise | 10° | C./minute |
| cooling rate | 5° | C./minute |
| holding time | 15 | minutes |

(*) The heating temperature is the SPS display temperature, and, based on the relationship for the temperature measurement method, the material temperature during heating is thought to be 350 ± 50 to 100° C.

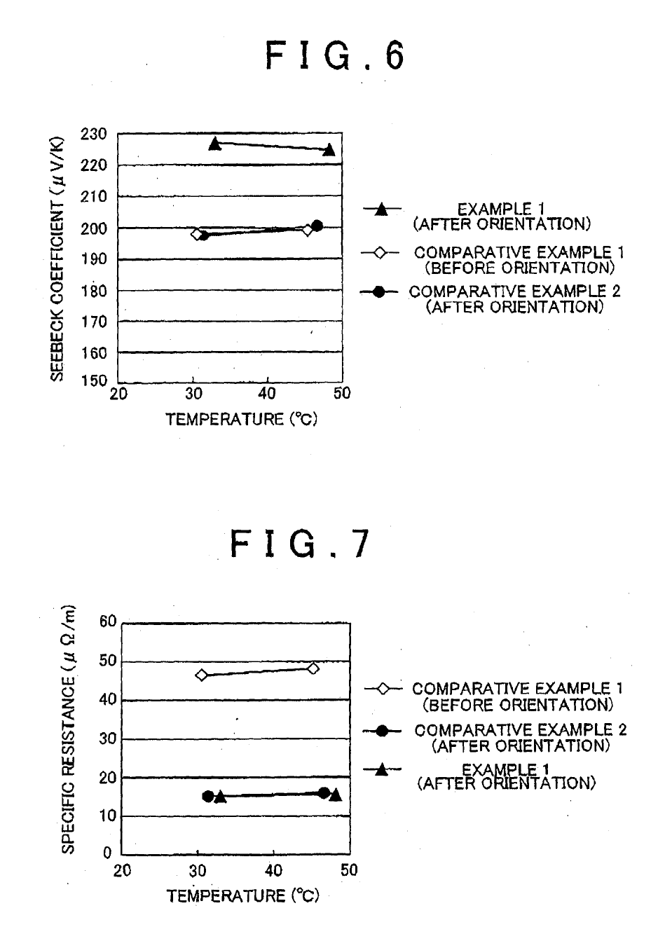

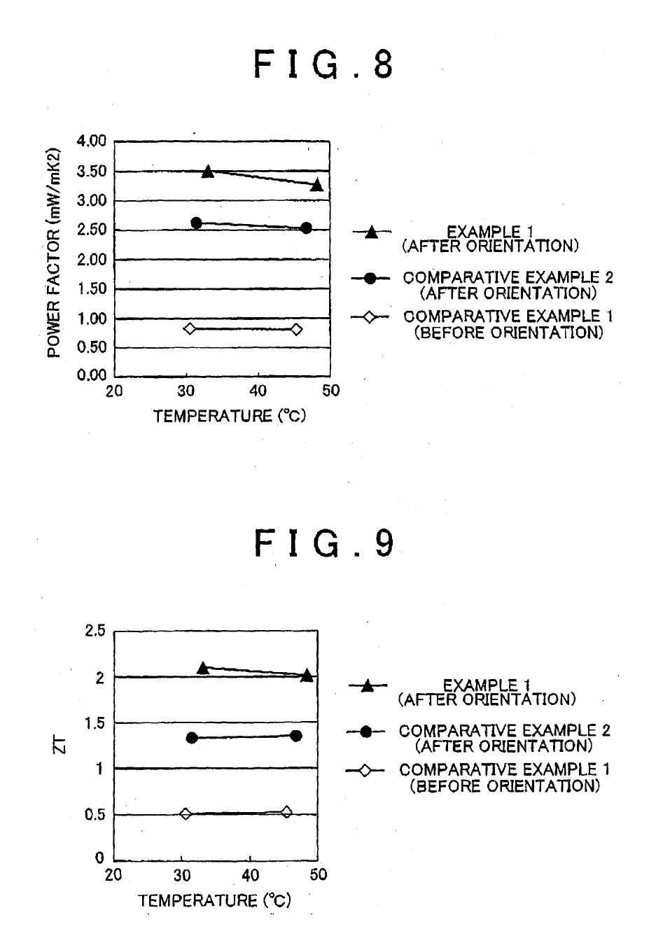

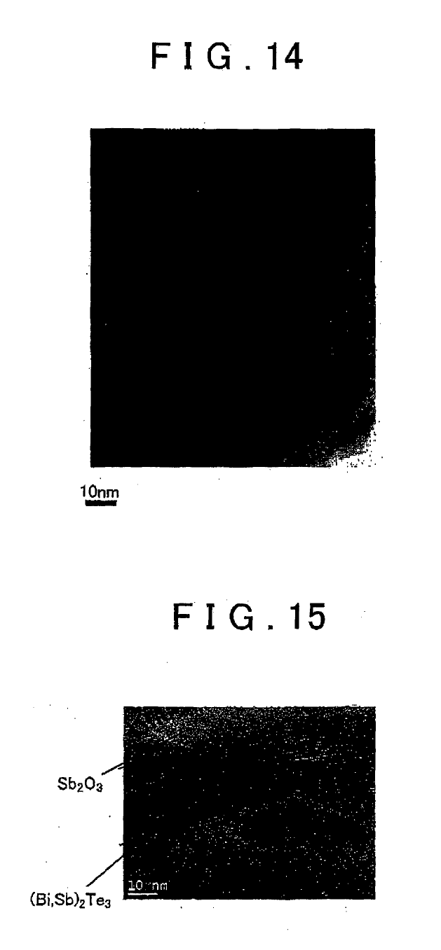

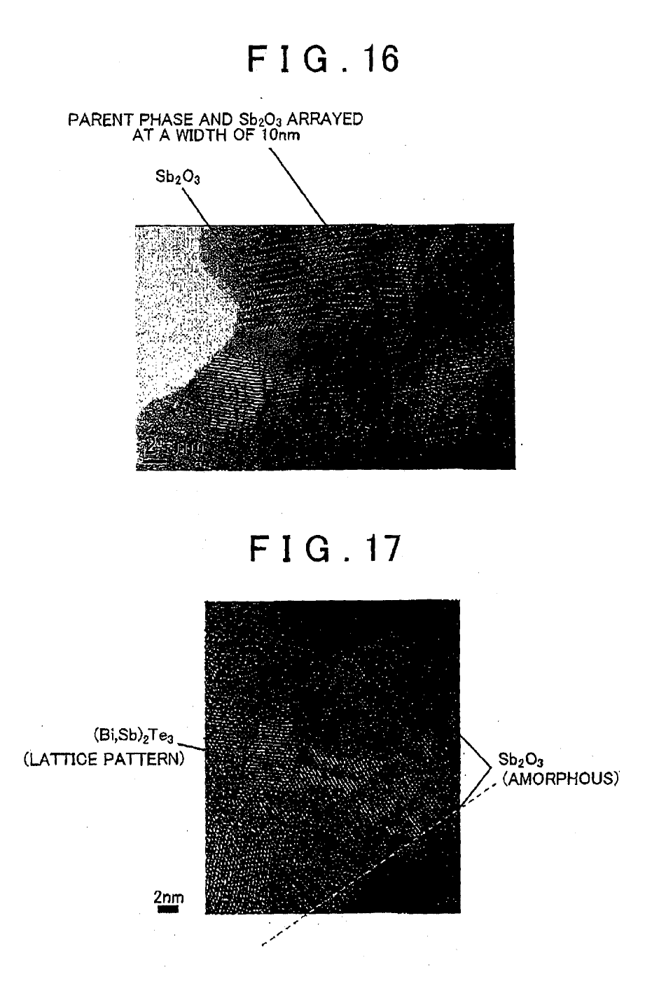

The obtained nanocomposite thermoelectric conversion material was evaluated. Along with the results for the comparative examples, FIG. 6 shows the Seebeck coefficient; FIG. 7 shows the specific resistance; FIG. 8 shows the power factor; FIG. 9 shows ZT; FIGS. 13, 14, and 16 show reproductions (view A) of high-amplification TEM images taken by high-resolution TEM; FIG. 15 shows a reproduction (view A) of a medium-amplification TEM image; and FIG. 17 shows a reproduction (view B) (cross section direction) of a high-amplification TEM image. According to FIGS. 13 and 14, which give high-amplification TEM images, the (Bi,Sb)₂Te₃ parent phase and Sb₂O₃ are arrayed at a width of 5 to 10 nm, that is not more than 10 nm, approximately in parallel. According to FIG. 15, which shows a medium-amplification TEM image, and FIG. 16, which shows a high-amplification TEM image, the (Bi,Sb)₂Te₃ parent phase and Sb₂O₃ are arrayed at a width of 5 to 10 nm, that is not more than 10 nm, approximately in parallel; Sb₂O₃ particle diameters of 3 to 50 nm are observed; and parent phase particle diameters of approximately 10 nm are observed. In addition, in FIG. 17, which is a view from the cross section direction, amorphous Sb₂O₃ and the lattice pattern of the (Bi,Sb)₂Te₃ parent phase are observed.

### Reference Example 1

### Related Art

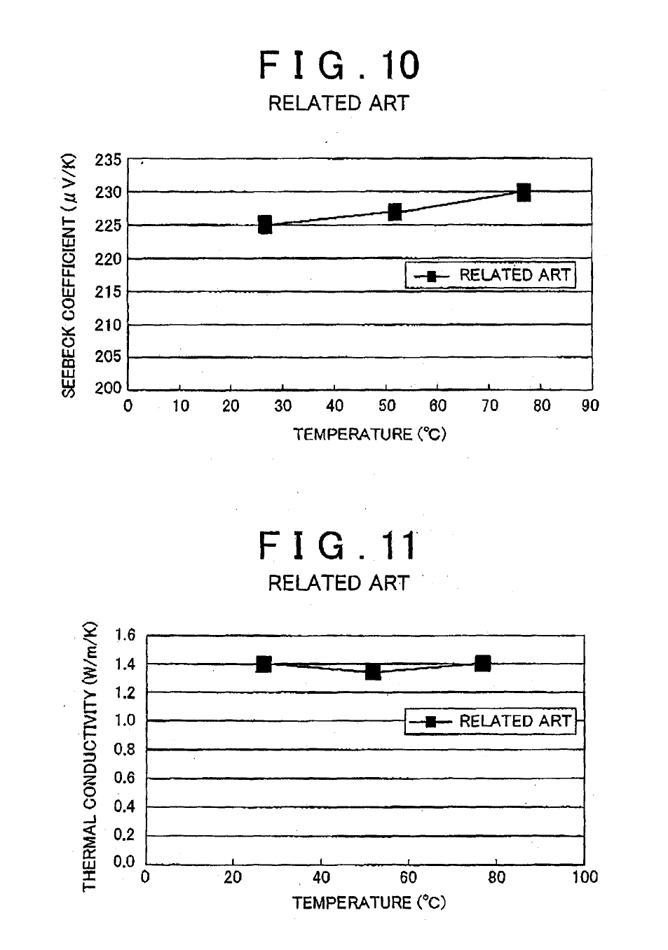

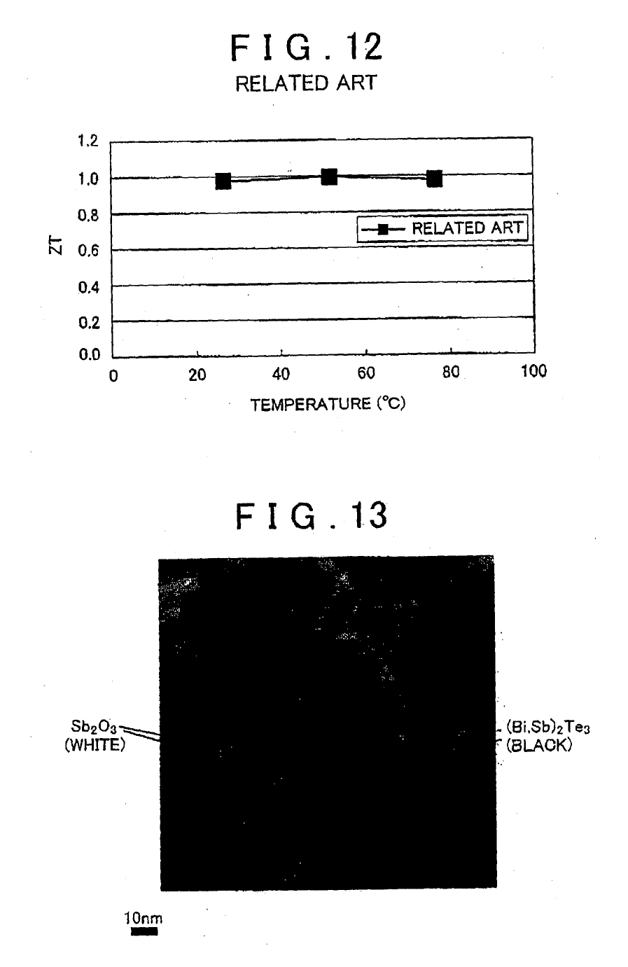

Based on the technology described in Journal of Crystal Growth, 277 (2005) 258-263, a crystalline material was produced by synthesis of an ingot material under seal in quartz and zone melting. The obtained thermoelectric material was evaluated. The Seebeck coefficient is shown in FIG. 10; the thermal conductivity is shown in FIG. 11; and ZT is shown in FIG. 12.

### Comparative Example 1

An evaluation was performed on the nanocomposite thermoelectric conversion material bulk body provided by bulk body production as in Example 1, but which had not been subjected to compression processing. Along with the results for Example 1, the Seebeck coefficient is shown in FIG. 6; the specific resistance is shown in FIG. 7; the power factor is shown in FIG. 8; and ZT is shown in FIG. 9.

### Comparative Example 2

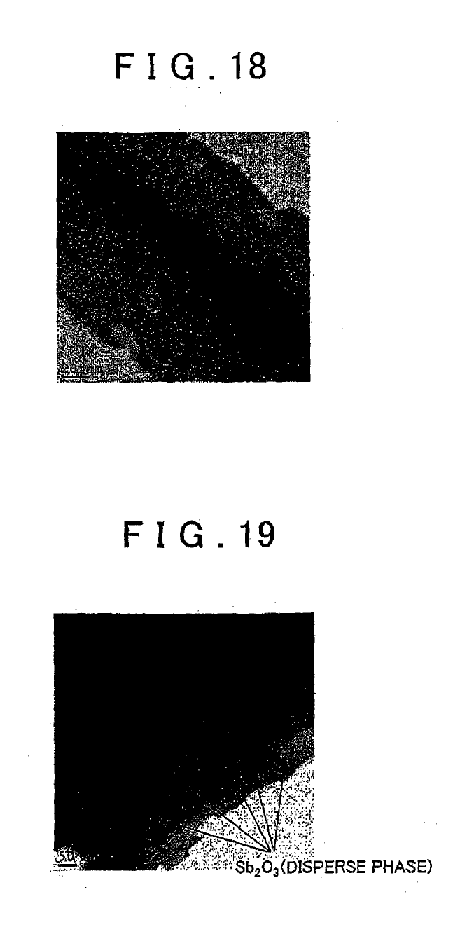

The same procedure as in Example 1 was carried out, with the exception that the cooling rate was changed from 5° C./minute to 20° C./minute by ohmic heating (SPS), and the obtained nanocomposite thermoelectric conversion material was evaluated. Along with other results, the Seebeck coefficient is shown in FIG. 6; the specific resistance is shown in FIG. 7; the power factor is shown in FIG. 8; ZT is shown in FIG. 9; and reproductions of high-amplification TEM images are shown in FIGS. 18 and 19. In FIG. 18, the white contrast is Sb₂O₃ (disperse phase) and the black contrast is (Bi,Sb)₂Te₃ (parent phase).

By carrying out the orientation of a thermoelectric material in which nanoparticles of a dispersant are dispersed in a thermoelectric material parent phase (matrix), the invention provides a Seebeck coefficient α that is improved, even at low temperatures, over that of the unoriented nanocomposite thermoelectric conversion material and thereby provides a nanocomposite thermoelectric conversion material having an increased power factor. The invention also provides a method of producing this nanocomposite thermoelectric conversion material and provides a nanocomposite thermoelectric conversion element.

1. A nanocomposite thermoelectric conversion material, comprising:
a thermoelectric material parent phase in which crystal grains are stacked in a laminar configuration and are oriented, and
a width of the crystal grains perpendicular to a direction of the orientation is in a range from at least 5 nm to less than 20 nm; and
insulating nanoparticles that are present dispersed at grain boundaries.

2. The nanocomposite thermoelectric conversion material according to claim 1, characterized in that the thermoelectric material is any selection from a (Bi,Sb)₂(Te,Se)₃ system, Bi₂Te₃ system, (Bi,Sb)Te system, Bi(Te,Se) system, CoSb₃ system, PbTe system, and SiGe system.

3. The nanocomposite thermoelectric conversion material according to claim 1, wherein the insulating nanoparticles are any selection from alumina, zirconia, titania, magnesia, silica, composite oxides containing the preceding, silicon carbide, aluminum nitride, and silicon nitride.

4. A method of producing a nanocomposite thermoelectric conversion material, comprising:
heating a material that has insulating nanoparticles dispersed in a thermoelectric material parent phase to a temperature that is higher than or equal to a softening point of the thermoelectric material; and
orienting crystal grains of the thermoelectric material parent phase by cooling under compression at a cooling rate of at least 1° C./minute to less than 20° C./minute.

5. The production method according to claim 4, characterized in that with a thickness compression rate of the material due to the cooling under compression being defined as [(thickness prior to compression of the material−thickness after compression of the material)×100/thickness prior to compression of the material] (%), the rate is in a range from 25 to 90%.

6. The production method according to claim 4, wherein pressure during the cooling under compression is in a range from 5 to 500 MPa.

7. A nanocomposite thermoelectric conversion material obtained by the method described according to claim 4.

8. A thermoelectric conversion element that contains the nanocomposite thermoelectric conversion material according to claim 1.
